(19) United States
(12) Patent Application Publication
(10) Pub. No.: US 2024/0079264 A1
(43) Pub. Date: Mar. 7, 2024

(54) SUBSTRATE SUPPORTING APPARATUS

(71) Applicant: Samsung Electronics Co., Ltd., Suwon-si (KR)

(72) Inventors: Jonggu Lee, Suwon-si (KR); Jeonggil Kim, Suwon-si (KR); Hyeonjin Kim, Suwon-si (KR); Kyoungwhan Oh, Suwon-si (KR)

(21) Appl. No.: 18/235,603

(22) Filed: Aug. 18, 2023

(30) Foreign Application Priority Data
Sep. 2, 2022 (KR) 10-2022-0111678

(51) Int. Cl. H01L 21/687; H01L 21/67

(52) U.S. Cl. CPC H01L 21/68742; H01L 21/67288; H01L 21/68785

(57) ABSTRACT

A substrate supporting apparatus includes a stage table configured to support a substrate and including a plurality of openings, a plurality of lift pins disposed to be vertically movable through the plurality of openings and configured to support the substrate, a lift support positioned outside the stage table from a plan view and vertically movable to support the substrate, an actuator configured to vertically actuate the plurality of lift pins and the lift support so as to load the substrate onto the stage table, and a controller configured to control the actuator.

### CROSS-REFERENCE TO RELATED APPLICATION

This application is based on and claims priority under 35 U.S.C. § 119 to Korean Patent Application No. 10-2022-0111678, filed on Sep. 2, 2022, in the Korean Intellectual Property Office, the disclosure of which is incorporated by reference herein in its entirety.

### BACKGROUND

Aspects of the inventive concept relate to a substrate supporting apparatus, and more particularly, relate to a substrate supporting apparatus for loading and unloading a substrate.

In general, a semiconductor device may be manufactured through a plurality of unit processes. The unit processes may include a thin film deposition process, a diffusion process, a heat treatment process, a photolithography process, a polishing process, an etching process, an ion injection process, and a cleaning process. In order to perform the various processes described above, a substrate typically needs to be seated on a stage table inside a chamber in which processes are performed. Protrusions may be formed on an upper surface of the stage table to support the substrate.

### SUMMARY

Aspects of the inventive concept provide a substrate supporting apparatus capable of minimizing the occurrence of overlay by preventing damage to protrusions on a table surface.

According to an aspect of the inventive concept, a substrate supporting apparatus includes a stage table configured to support a substrate and including a plurality of openings, a plurality of lift pins disposed to be vertically movable through the plurality of openings and configured to support the substrate, a lift support positioned outside the stage table from a plan view and vertically movable to support the substrate, an actuator configured to vertically actuate the plurality of lift pins and the lift support so as to load the substrate onto the stage table, and a controller configured to control the actuator.

According to another aspect of the inventive concept, a substrate supporting apparatus includes a stage table configured to support a substrate and including a plurality of openings, a plurality of lift pins disposed to be vertically movable through the plurality of openings and configured to support the substrate, a lift support positioned outside the stage table from a plan view and vertically movable to support the substrate, an actuator configured to vertically actuate the plurality of lift pins and the lift support so as to load the substrate onto the stage table, a controller configured to control the actuator, and an overlay measurement apparatus positioned on the stage table and configured to measure an overlay between patterns formed on the substrate.

According to another aspect of the inventive concept, a substrate supporting apparatus includes a stage table configured to support a substrate and including a plurality of openings, a plurality of lift pins disposed to be vertically movable through the plurality of openings and configured to support the substrate, a plurality of lift members positioned outside the stage table from a plan view, disposed spaced apart from each other along a circumference of the stage table, and vertically movable to support the substrate, an actuator configured to control a vertical movement of the plurality of lift pins and the plurality of lift members so as to load the substrate onto the stage table, and a controller configured to control the actuator. The lift member includes a dielectric positioned to contact and support the substrate and an electrode buried in the dielectric and connected to a power source configured to generate electrostatic force for fixing the substrate loaded onto an upper surface of the stage table, the stage table includes a plurality of protrusions disposed at a certain pitch on an upper surface of the stage table to support the substrate, wherein the actuator is configured to lower the plurality of lift pins until an upper surface of each of the plurality of lift pins is at least equal to a height of the upper surface of the stage table, and independently actuate the vertical movement of the plurality of lift pins and the plurality of lift members, and a horizontal cross sectional shape of an upper surface of each lift member is in a circular or bow shape, and an area of the upper surface of each lift member is larger than an area of the upper surface of each of the plurality of lift pins.

### BRIEF DESCRIPTION OF THE DRAWINGS

Embodiments will be more clearly understood from the following detailed description taken in conjunction with the accompanying drawings in which:

FIG. 1 is a cross-sectional view showing a semiconductor manufacturing apparatus including a substrate supporting apparatus according to an embodiment;

FIG. 2 is a schematic cross-sectional view of an exposure apparatus including a substrate supporting apparatus according to an embodiment;

FIGS. 3 to 5 are cross-sectional views illustrating a splitting phenomenon of protrusions formed on a stage table;

FIG. 6 is a block diagram illustrating an overlay measurement apparatus according to an embodiment;

FIG. 7 is a cross-sectional view of a substrate supporting apparatus according to an embodiment;

FIG. 8 is a plan view of some components of the substrate supporting apparatus according to an embodiment;

FIG. 9 is a plan view of some components of a substrate supporting apparatus according to another embodiment;

FIG. 10 is a plan view of some components of a substrate supporting apparatus according to another embodiment;

FIG. 11 is a schematic cross-sectional view of a lift member according to an embodiment;

FIG. 12 is a schematic cross-sectional view of a lift member according to another embodiment;

FIGS. 13A to 13F are cross-sectional views schematically illustrating an operation process of a substrate supporting apparatus according to an embodiment; and

FIG. 14 is a flow chart showing a method of manufacturing a semiconductor device, according to an embodiment.

### DETAILED DESCRIPTION OF THE EMBODIMENTS

Hereinafter, embodiments of the inventive concept will be described in detail with reference to the accompanying drawings. However, the inventive concept does not have to be configured as limited to the embodiments described below and may be embodied in various other forms. The following embodiments are provided to fully convey the scope of the inventive concept to those skilled in the art.

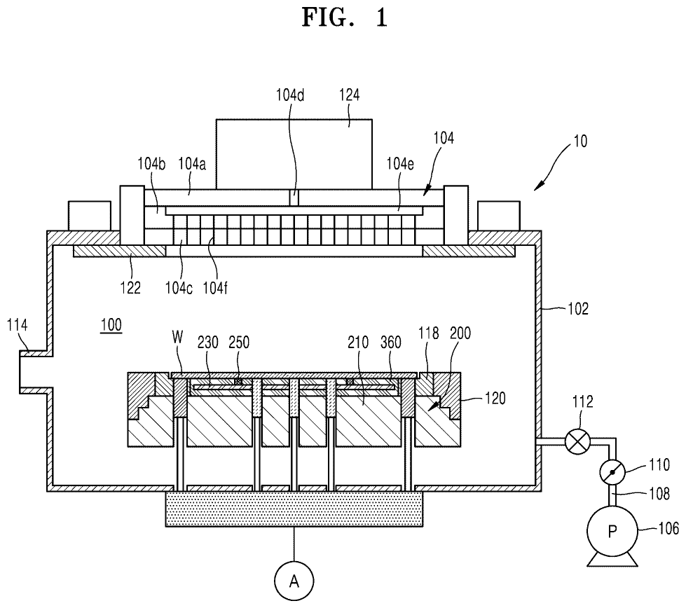

FIG. 1 is a cross-sectional view showing a semiconductor manufacturing apparatus 10 including a substrate supporting apparatus 100 according to an embodiment.

Referring to FIG. 1, the semiconductor manufacturing apparatus 10 includes a chamber 102 in which a processing process of a semiconductor substrate W is performed, an electrostatic chuck 200 included in the chamber 102 and supporting the semiconductor substrate W, and a plurality of first through holes 104d provided in the upper side (e.g., top side) of the chamber 102 and providing gas for processing the semiconductor substrate W into the chamber 102. In addition, the semiconductor manufacturing apparatus 10 may include an upper electrode 104 to which a radio frequency (RF) power source forming the gas into a plasma state is connected. The upper electrode 104 may include the first through holes 104d.

According to an embodiment, a vacuum pump 106 making the inside of the chamber 102 be in a vacuum state may be connected to one side of the chamber 102. A throttle valve 110 and a gate valve 112 that open and close a vacuum line 108 configured to adjust a degree of vacuum of the inside of the chamber 102 may be installed in the vacuum line 108 connecting the chamber 102 to the vacuum pump 106.

In addition, a door 114, or opening, through which the semiconductor substrate W may be moved may be provided at one side of the chamber 102. Although not shown, the semiconductor substrate W may be moved between the outside of the chamber 102 and the inside of the chamber 102 by a transfer arm.

The electrostatic chuck 200 may include a ceramic plate 210 and a plate electrode 230. A plurality of gas supply holes (not shown) may be formed in the ceramic plate 210 to provide gas for adjusting the temperature of the semiconductor substrate W to the lower surface of the semiconductor substrate W. Also, the plate electrode 230 may be buried inside the ceramic plate 210. The substrate supporting apparatus 100 may be provided on the electrostatic chuck 200. The substrate supporting apparatus 100 may be configured such that semiconductor substrate W may be seated within the chamber 102. The substrate supporting apparatus 100 may include a stage table 360 supporting the semiconductor substrate W, a lift pin holding the semiconductor substrate W, and a lift member, which will be described in detail below.

According to an embodiment, a focus ring 118, for example made of silicon, to guide plasma to the semiconductor substrate W may be provided at an edge of the electrostatic chuck 200 on which the semiconductor substrate W is loaded. A cover ring 120, for example made of quartz, may be provided outside the focus ring 118 for insulation, and an upper ring 122 guiding the plasma to the semiconductor substrate W may be provided at the edge of the lower surface of the upper electrode 104.

The chamber 102 may be described as having an upper side, lower side, and vertical sides connecting the upper side to the lower side. The upper electrode 104 is provided on the upper side of the chamber 102 and may include a first electrode 104a, a second electrode 104b, and a third electrode 104c. For example, each of the first electrode 104a and the second electrode 104b may be made of aluminum, and the third electrode 104c may be made of silicon. An RF power source may be connected to the first electrode 104a, and a first through hole 104d (e.g., plurality of first through holes 104d) connected to a gas supplier outside the chamber 102 may be formed in the first electrode 104a.

A space 104e accommodating gas for processing the semiconductor substrate W may be formed between the first electrode 104a and the second electrode 104b, and a plurality of second through holes 104f uniformly supplying the gas into the chamber 102 may be formed in the second electrode 104b and the third electrode 104c.

When the semiconductor substrate W is transferred to the upper portion of the electrostatic chuck 200 by the transfer arm, the semiconductor substrate W is loaded onto the stage table 360 of the substrate supporting apparatus 100 by elevation of the lift pin. The semiconductor substrate W may be fixed on the stage table 360 by the electrostatic force of the electrostatic chuck 200, and a processing process may be performed by a process gas formed in a plasma state.

According to an embodiment, the temperature of the semiconductor substrate W may rise by high-temperature plasma. The rising temperature of the semiconductor substrate W may be controlled by helium gas supplied to the back surface of the semiconductor substrate W through a plurality of gas supply holes (not shown) formed in the ceramic plate 210. In addition, the temperature of the stage table 360, which greatly affects the temperature of the semiconductor substrate W, may be effectively controlled by the helium gas flowing through the gas supply holes.

According to an embodiment, when the semiconductor substrate W on which the semiconductor manufacturing process has been performed is unloaded from the upper surface of the electrostatic chuck 200, a ground unit 250 discharging charges remaining on the semiconductor substrate W may be included in the electrostatic chuck 200. The ground unit 250 may have a structure including a ground pin, a spring determining the height of the ground pin, a bushing accommodating the ground pin and the spring to insulate the ground pin and the spring from a stage, and a fastener fastening bushing accommodating the ground pin and the spring to the stage table 360.

In particular, the fastener of the ground unit 250 further includes a fixing pin fastened to a recess formed on the side surface of the bushing in a tight fit scheme, and thus, when the semiconductor substrate W is repeatedly loaded and unloaded, a problem in which the upper end of the bushing protrudes from the upper surface of the stage table 360 due to loosening of the fastening may be prevented.

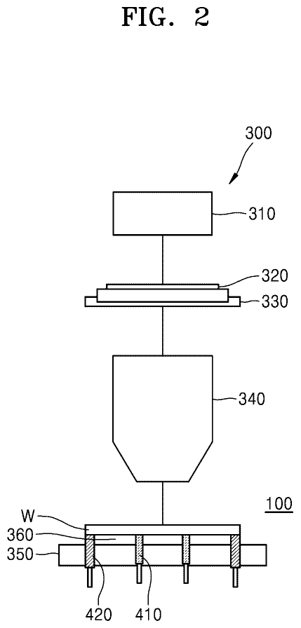

FIG. 2 is a schematic cross-sectional view of an exposure apparatus 300 according to aspects of the inventive concept.

Referring to FIG. 2, the exposure apparatus 300 may include an illumination system 310, a reticle stage 330 on which a reticle 320 is seated, a projector 340, a stage 350 capable of performing horizontal linear reciprocating motion, and the substrate supporting apparatus 100.

The substrate supporting apparatus 100 may be configured such that the semiconductor substrate W may be seated inside a chamber in which an exposure process is performed. The substrate supporting apparatus 100 may include the stage table 360 supporting a substrate, a lift pin 410 supporting the substrate, and a lift member 420, which will be described in detail below.

The semiconductor substrate W is loaded onto the stage table 360. A photoresist film (not shown) is formed on the semiconductor substrate W, and is formed into a photoresist pattern through an exposure process and a development process. The photoresist film is formed on the semiconductor substrate W through a photoresist composition coating process and a soft bake process, and the photoresist pattern formed through these processes may be used as an etching mask or an ion injection mask. A plurality of shot regions are set on the semiconductor substrate W, and each shot region may include at least one die region. The size of the die region may be changed according to the type of a desired semiconductor device, and the size of each shot region and the number of shot regions may be determined according to the size of the die region.

The illumination system 310 generates light for exposure. The illumination system 310 may include, for example, one or more of a mercury lamp, an argon fluoride (ArF) laser generator, a krypton fluoride (KrF) laser generator, and an extreme ultraviolet beam or an electron beam generator.

According to an embodiment, light generated from the illumination system 310 illuminates the reticle 320 disposed on the reticle stage 330. A certain circuit pattern is formed on the reticle 320 to be projected onto the shot region of the semiconductor substrate W. The light irradiated to the reticle 320 passes through the reticle 320 and reflects image information of the circuit pattern. In this case, the reticle 320 may be moved in a certain direction by the reticle stage 330.

According to an embodiment, light passing through the reticle 320 is irradiated onto the projector 340. The projector 340 performs a focus latitude extended exposure (FLEX) process by radiating light reflecting the image information of the circuit pattern onto the semiconductor substrate W at multiple focal points. FLEX technology is technology of overlapping a circuit pattern image of the reticle 320 on the semiconductor substrate W at multiple focal points, which may increase an image formation margin as well as a depth of focus (DOF).

The upper end of the projector 340 is disposed to face the reticle 320 and the lower end thereof is disposed to face the semiconductor substrate W. Although not specifically shown, a first projection lens into which light passing through the reticle 320 is incident may be disposed at the upper end of the projector 340, and a second projection lens through which the light incident through the first projection lens is emitted may be disposed at the lower end of the projector 340. Accordingly, the light passing through the reticle 320 and incident to the first projection lens may be emitted through the second projection lens. The light passing through the second projection lens is irradiated onto the semiconductor substrate W. This light may cause a photoresist on the substrate to be patterned, which pattern may then be used for an etching or deposition process, for example.

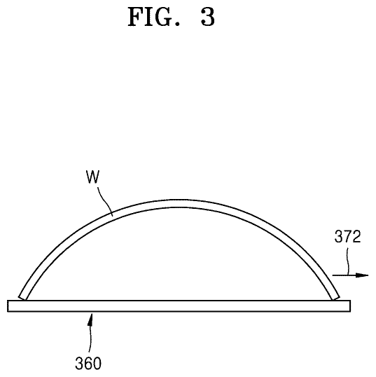

FIGS. 3 to 5 are cross-sectional views illustrating a splitting phenomenon of protrusions 362 formed on the upper surface of the stage table 360.

Referring to FIG. 3, when the semiconductor substrate W is loaded onto the stage table 360, a part of the semiconductor substrate W contacts an edge region of the stage table 360. For example, an edge region of the semiconductor substrate W that is convex upward may contact the edge region of the stage table 360. As the semiconductor substrate W is loaded onto the stage table 360 and pressed toward a planar shape, the edge region may slide over the upper surface of the stage table 360 in a generally outward direction as indicated by an arrow 372. The edge region of the semiconductor substrate W sliding on the edge region of the stage table 360 may scratch or remove the surface of the stage table 360 and damage the stage table 360.

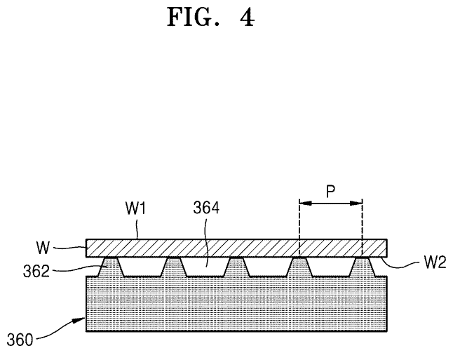

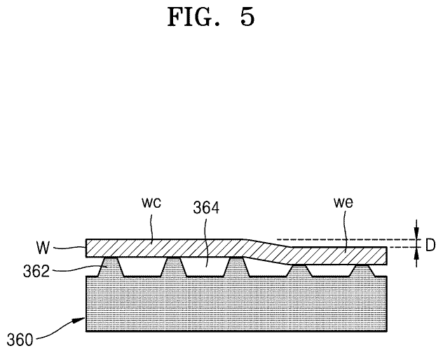

Referring to FIGS. 4 and 5, the stage table 360 may include the plurality of protrusions 362 formed on the upper surface thereof to support the semiconductor substrate W. The plurality of protrusions 362 may be formed at a constant pitch P on the upper surface of the stage table 360. Specifically, the pitch P may be a distance between centers of the plurality of protrusions 362. The pitch P may be different depending on the size of a semiconductor device. For example, when a 300 nm semiconductor device is formed, a substrate may require a smaller pitch P than the substrate when a 400 nm semiconductor device is formed.

As described above, the edge region of the stage table 360 may correspond to repeated loading of the semiconductor substrate W onto the stage table 360 and may experience wear. The semiconductor substrate W may have an upper surface W1 and a lower surface W2. Specifically, the protrusions 362 of the stage table 360 may experience wear due to repeated friction with the lower surface W2 of the semiconductor substrate W. According to an embodiment, the protrusions 362 formed on the edge region of the stage table 360 supporting an edge region we of the semiconductor substrate W may be worn as shown in FIG. 5. As a result, the edge region we of the semiconductor substrate W may be loaded on the stage table 360 while drooping by a distance D compared to a central region we of the semiconductor substrate W. Continuous damage to the protrusions 362 of the stage table 360 may cause an imbalance in the arrangement of layers stacked on the semiconductor substrate W, which may lead to an overlay between the stacked layers.

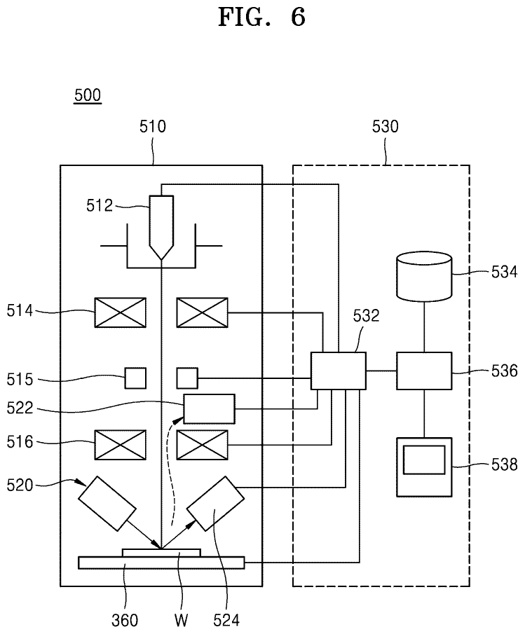

FIG. 6 is a block diagram illustrating an overlay measurement apparatus 500 according to an embodiment.

Referring to FIG. 6, the overlay measurement apparatus 500 may include an electron optical system 510 irradiating an electron beam on a sample such as the semiconductor substrate W configured as a multilayer structure and detecting emitted electrons and a processor 530 obtaining and analyzing images from the electrons detected by the electronic optical system 510 and calculating an overlay between an upper layer and a lower layer of the multilayer structure.

The overlay measurement apparatus 500 may be used to calculate the overlap between the upper layer and the lower layer on the semiconductor substrate W configured as the multilayer structure after a process of the semiconductor substrate W seated on the stage table 360 ends.

According to an embodiment, the overlay measurement apparatus 500 may be used to measure an overlay between a previously patterned first layer and a currently patterned second layer in a non-destructive method, in a semiconductor manufacturing process of manufacturing semiconductor devices such as DRAM and VNAND. Specifically, the overlay measurement apparatus 500 may measure an overlay between patterns between a first layer and a second layer included in the multilayer structure formed on the semiconductor substrate W after the semiconductor substrate W is loaded onto the stage table 360.

According to an embodiment, the electronic optical system 510 of the overlay measurement apparatus 500 may include a scanning electron microscope (SEM) imaging the semiconductor substrate W configured as a multilayer structure. Specifically, the SEM may be a high-acceleration SEM. The SEM may include the stage table 360 supporting the semiconductor substrate W, an electron gun 512 generating a primary electron beam, and controlling the direction and width of the primary electron beam, a focusing lens 514 controlling the direction and width of the primary electron beam and irradiating the primary electron beam onto the semiconductor substrate W, a deflector 515, n objective lens 516, and a detector 520 detecting a detection signal such as electrons emitted from the semiconductor substrate W.

According to an embodiment, the semiconductor substrate W may have a multilayer structure in which upper and lower patterns overlap each other. The layer may include, but is not limited to, a photoresist, a dielectric material, and a conductive material.

According to an embodiment, the depth of the primary electron beam penetrating the semiconductor substrate W may be adjusted by adjusting an acceleration voltage of the primary electron beam formed by the electron gun 512 to a low voltage or a high voltage. For example, the electron gun 512 may generate an electron beam having an accelerating voltage equal to or greater than about 10 kV. The higher the acceleration voltage of the electron beam, the greater the depth of the primary electron beam penetrating the semiconductor substrate W, and accordingly, the amount of electrons emitted from the lower layer of the semiconductor substrate W increases, thereby detecting electrons having substructure information.

Also, the electronic optical system 510 may include the detector 520 detecting electrons emitted from the semiconductor substrate W. The detector 520 may include a first detector 522 that primarily detects secondary electrons and a second detector 524 that primarily detects backscattered electrons. The second detector 524 may include a detector for backscattered electrons disposed adjacent to the objective lens 516 and mainly having substructure information. The detected electrons may be used to generate an actual image of the semiconductor substrate W as described below.

The overlay measurement apparatus 500 may include an image processing unit 532 that receives a detection signal from the detector 520 and forms an image. The image processing unit 532 may receive detection signals from the first and second detectors 522 and 524 and obtain SEM images simultaneously representing upper and lower structures of the semiconductor substrate W. In addition, the image processing unit 532 may be operatively connected to various components of the electronic optical system 510 including the electron gun 512, the focusing lens 514, the deflector 515, the objective lens 516, and the stage table 360 and may control operations of the components. The SEM images obtained by the image processing unit 532 may be selectively stored in a data storage 534.

The overlay measurement apparatus 500 may include an image processing unit 536 comparing a design image with each of the first and second images with respect to the design image of the patterns, and calculating an overlay between an upper pattern and a lower pattern. Overlay refers to an amount of misalignment in the horizontal direction between stacked patterns.

At least one of the image processing unit 532, the image processing unit 536, the data storage 534, or an outputter 538 shown in FIG. 6 may be implemented as a single computer or the processor 530 or may be implemented as separate modules using data transmission or interfacing means. For example, these components can be implemented with one or more of the following: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the processing controller 1020 (e.g., keyboard, mouse, display, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored.

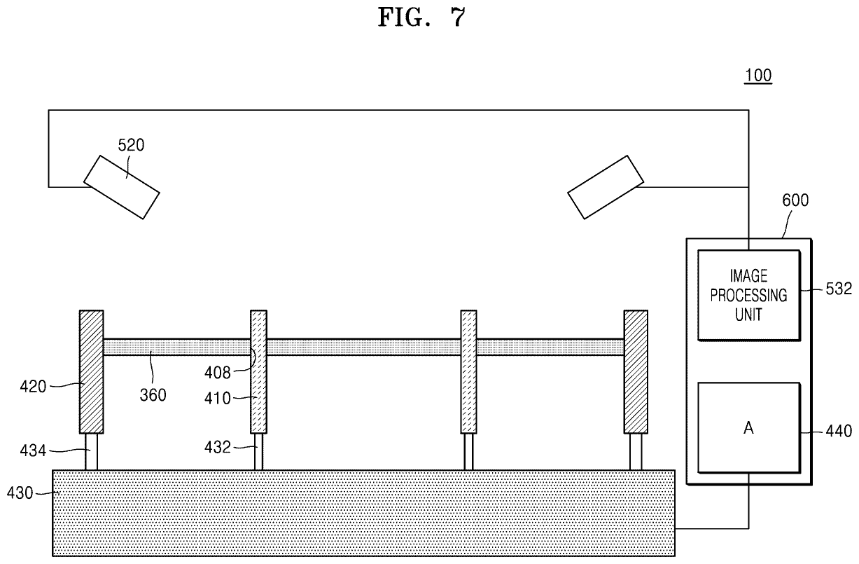

FIG. 7 is a cross-sectional view of the substrate supporting apparatus 100 according to an embodiment.

Referring to FIG. 7, the substrate supporting apparatus 100 may include the stage table 360, the lift pin 410, the lift member 420, an actuator 430, and a controller 600. The stage table 360 may support a substrate and include a plurality of openings 408.

According to an embodiment, the lift pin 410 may be disposed to be vertically movable through the opening 408 of the stage table 360. The lift pins 410 may support the substrate toward the stage table 360, wherein the substrate is placed above the stage table 360 using a transfer arm. A first rod 432 connected to the actuator 430 and configured to move vertically may be positioned on the lower portion of the lift pin 410.

The lift member 420 may be positioned outside the stage table 360 to be vertically movable. The lift member 420 may support the substrate toward the stage table 360, wherein the substrate is placed above the stage table 360 through the transfer arm. A second rod 434 connected to the actuator 430 and configured to vertically move may be positioned on the lower portion of the lift member 420.

The actuator 430 may vertically actuate the lift pin 410 and the lift member 420 to seat the substrate on the stage table 360. The actuator 430 may be a mechanical device used to physically operate or control the lift pin 410 and the lift member 420 based on a signal output from an actuator controller 440 of the controller 600. For example, the actuator 430 may include a pneumatic actuator, an electric actuator (e.g., motor), a hydraulic actuator, and/or an electric-hydraulic actuator.

The controller 600 may be configured to output a signal to and control the actuator 430. The controller 600 may be a computer device such as a workstation computer, a desktop computer, a laptop computer, a tablet computer, etc. For example, the controller 600 may include a memory device such as read only memory (ROM), random access memory (RAM), etc., and a processor configured to perform certain operations and algorithms, such as a microprocessor and a central processing unit (CPU), a graphics processing unit (GPU), etc. The controller 600 may output the signal to the actuator 430 so that the lift pin 410 and the lift member 420 may independently actuate. Thus, the actuator 430 may include separate components (e.g., separate motors, hydraulics, etc.) that can be controlled separately and independently by the controller 600.

According to an embodiment, the substrate supporting apparatus 100 may include the overlay measurement apparatus 500. The detector 520 of the overlay measurement apparatus 500 may be connected to the image processing unit 532 and positioned on the stage table 360. The overlay measurement apparatus 500 may measure an overlay between patterns formed on a substrate after the substrate is seated on the stage table 360. The overlay measurement apparatus 500 has been described with reference to FIG. 5, and thus, a detailed description thereof is omitted below.

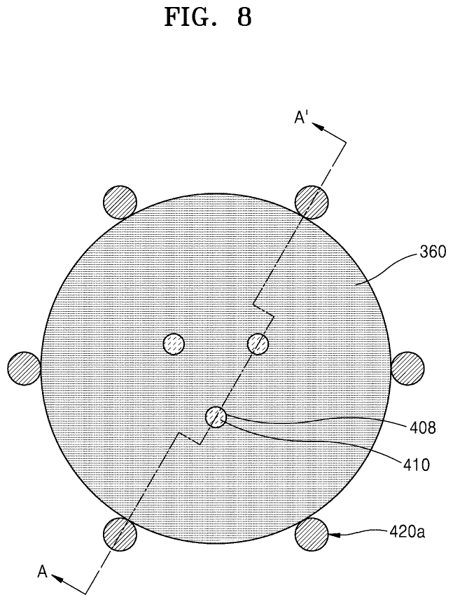

FIG. 8 is a plan view of some components of the substrate supporting apparatus 100 according to an embodiment.

According to an embodiment, the substrate supporting apparatus 100 may include the stage table 360, the lift pin 410, a lift member 420a, the actuator (see 440 in FIG. 7), and the controller (see 600 in FIG. 7). Though certain components, such as pins and members are described in singular, as can be seen in the drawings, they may be implemented in plural. Specifically, the stage table 360 may support the semiconductor substrate W loaded through a transfer arm, the lift pins 410, and the lift members 420a, and may include the plurality of openings 408. The lift pins 410 are disposed to be vertically movable through the opening 408 and support the semiconductor substrate W vertically descending after being placed above the stage table 360 by the transfer arm. In the drawing, it is shown that three openings 408 are formed in the stage table 360, and three lift pins 410 are disposed through the three openings 408, but the inventive concept is not limited to the above number.

The lift member 420a may be positioned outside the stage table 360 to be vertically movable and support the semiconductor substrate W vertically descending after being placed above the stage table 360 by the transfer arm. In the drawing, it is shown that six lift members 420a are disposed at regular intervals around the circular stage table 360, but the inventive concept is not limited to the above number.

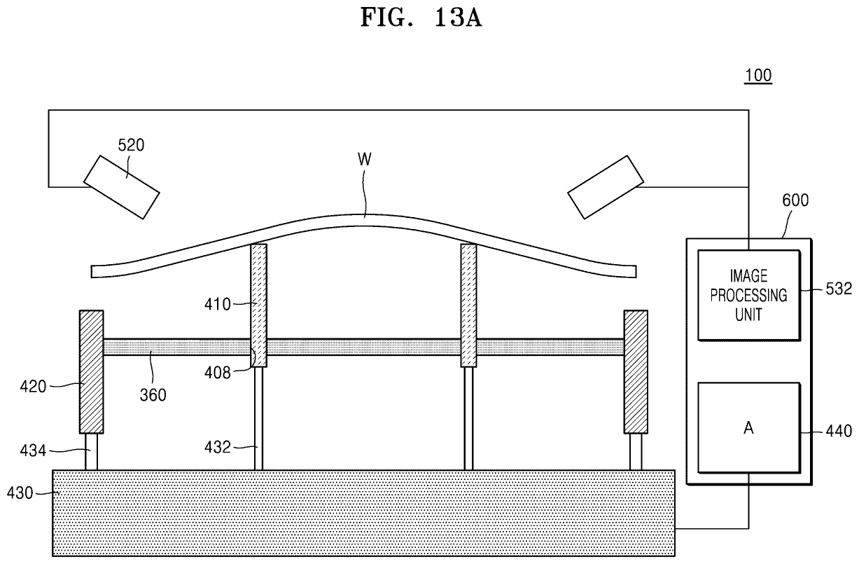

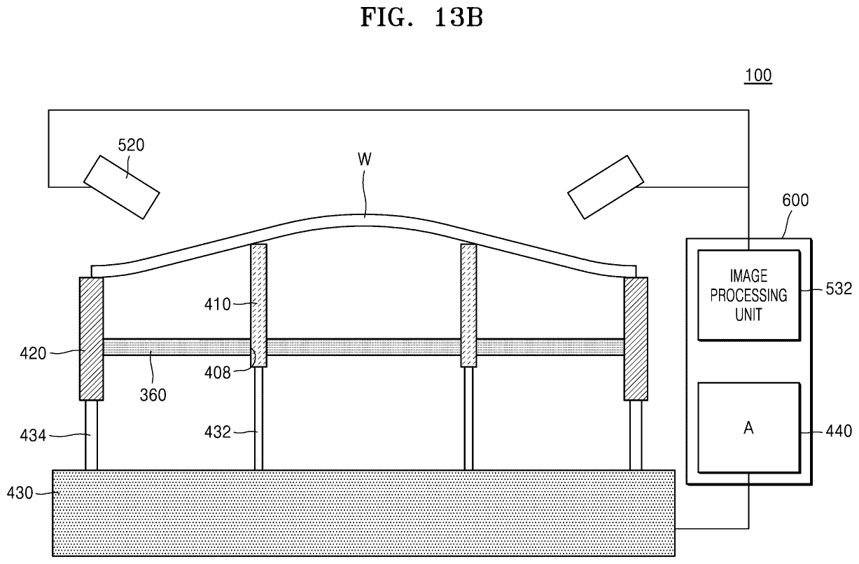

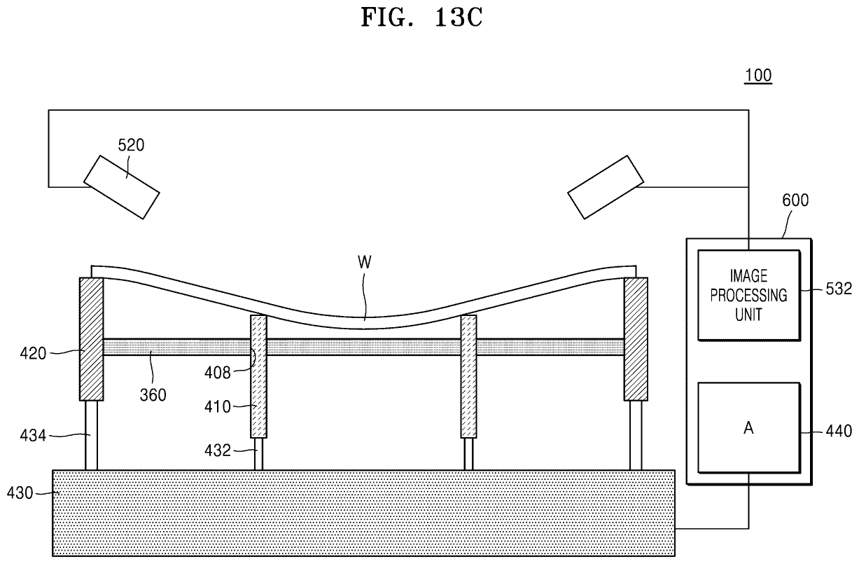

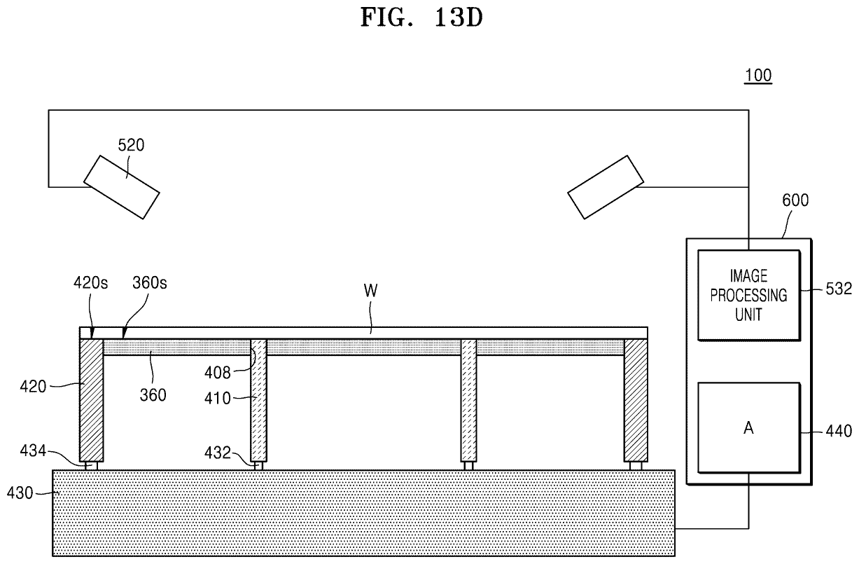

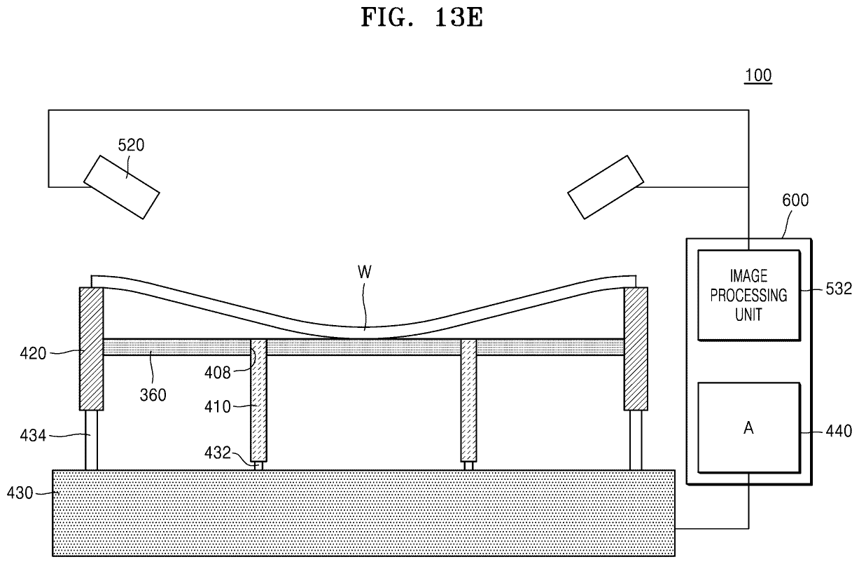

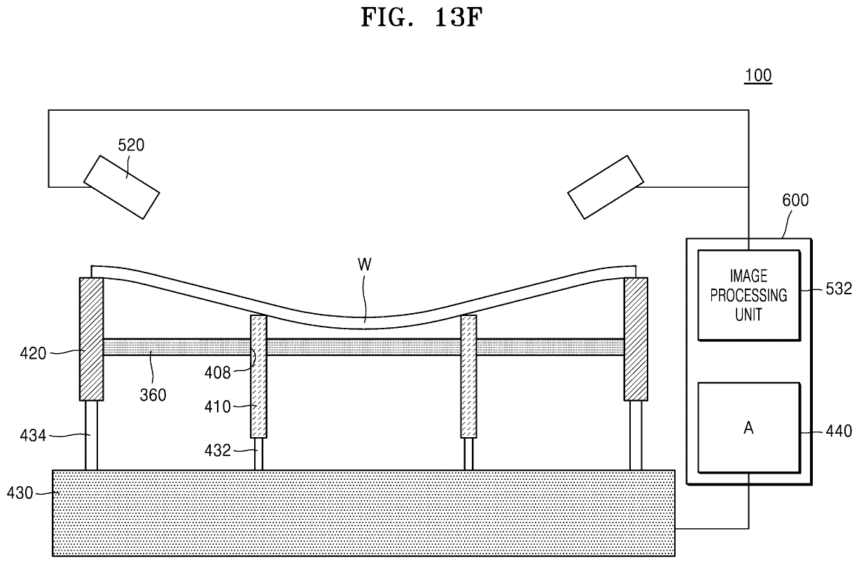

The actuator (see 440 in FIG. 7) may vertically actuate the lift pin 410 and the lift member 420a in order to load the semiconductor substrate W vertically descending onto the stage table 360, and the controller (see 600 in FIG. 7) may control the actuator 440. The actuator and the controller will be in detail described below with reference to FIGS. 13A to 13F.

According to an embodiment, there are a plurality of lift members 420a, and the plurality of lift members 420a may be spaced apart from each other along the circumference of the stage table 360. The number of lift members 420a is not limited, but may be an even number for stable loading of the semiconductor substrate W. For example, the even number of lift members 420a may be symmetrically disposed with respect to the center of the upper surface of the circular stage table 360. Alternatively, an odd number of lift members 420a may also be disposed in radial symmetry with respect to a center point of the upper surface of the circular stage table 360.

According to an embodiment, the horizontal shape of the upper surface of the lift member 420a may be circular. Also, in order to stably load the semiconductor substrate W vertically descending onto the stage table 360, the area of the upper surface of the lift member 420a may be larger than that of the upper surface of the lift pin 410. The lift pins 410 described herein may be pins having a cylindrical or rod shape, and may be described as rods or cylinders. The lift members 420a may also be pins, which as discussed above, may have a larger diameter (e.g., larger area at an upper surface) than the lift pins 410. The lift members 420a may also have a rod shape, or cylinder shape, and may be described as rods or cylinders. Lift pins 410, lift members 420a, and other lift members described herein may also be described as lift supports, with the supports formed to pass through holes in the stage table 360 being described as inner lift supports, and the supports formed outside of the stage table 360 (from a plan view) being described as outer lift supports. A plurality of lift members 420a may be described together as a lift support.

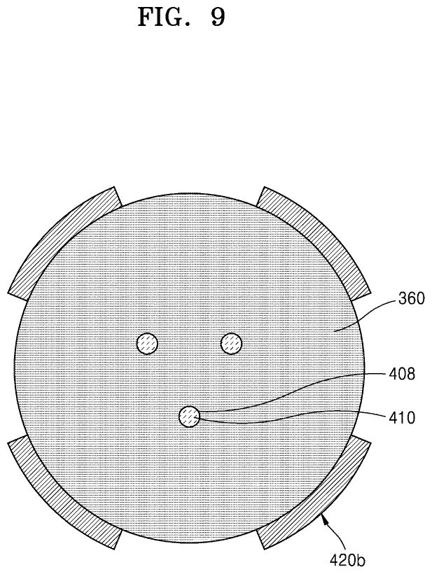

FIG. 9 is a plan view of some components of the substrate supporting apparatus 100 according to another embodiment.

In comparison with FIG. 8, FIG. 9 may be substantially the same as or similar to FIG. 8 except that the shape of a lift member 420b is different. The same reference numerals as in FIG. 8 denote the same members. In FIG. 9, the same descriptions as those in FIG. 8 are briefly given or omitted.

The lift member 420b may be positioned outside the stage table 360 to be vertically movable and support the semiconductor substrate W vertically descending after being placed above the stage table 360 by a transfer arm. In the drawing, it is shown that four lift members 420b are disposed at regular intervals around the circular stage table 360, but the inventive concept is not limited to the above number.

According to an embodiment, there are a plurality of lift members 420b, and the plurality of lift members 420b may be spaced apart from each other along the circumference of the stage table 360. The number of lift members 420b is not limited, but may be an even number for stable loading of the semiconductor substrate W. For example, the even number of lift members 420b may be disposed symmetrically with respect to the center of the upper surface of the circular stage table 360.

According to an embodiment, the horizontal shape of the upper surface of the lift member 420b may be a bow shape, or arc shape. Thus, the overall shape of each lift member 420b may be a bent or curved plate shape. The lift members 420b may be additionally described as lift plates, or curved lift plates. Also, in order to stably load the semiconductor substrate W vertically descending after being placed above the stage table 360 by the transfer arm onto the stage table 360, the area of the upper surfaces of the lift members 420b may be larger than that of the upper surfaces of the lift pins 410.

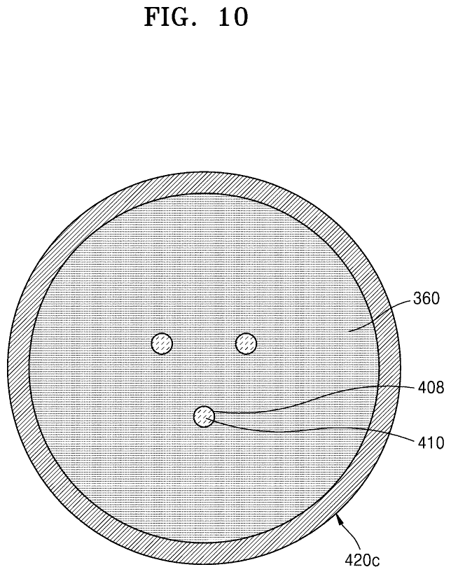

FIG. 10 is a plan view of some components of the substrate supporting apparatus 100 according to another embodiment.

In comparison with FIG. 8, FIG. 10 may be substantially the same or similar to FIG. 8, except that the shape of a lift member 420c is different. The same reference numerals as those in FIG. 7 denote the same members. In FIG. 9, the same descriptions as those in FIG. 7 are briefly given or omitted.

The lift member 420c may be positioned outside the stage table 360 to be vertically movable and support a substrate that vertically descends through a transfer arm. According to an embodiment, the horizontal shape of the upper surface of the lift member 420c may be a ring shape. The lift member 420c may be therefore additionally described as a lift cylinder or a lift tube.

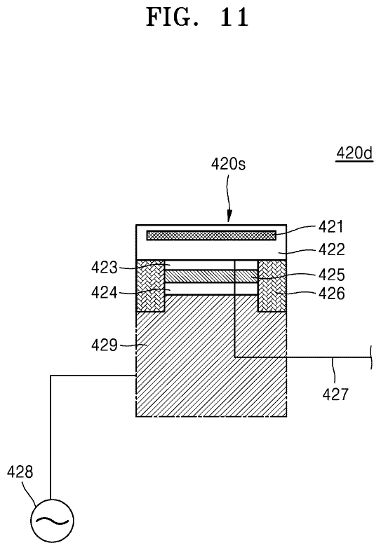

FIG. 11 is a schematic cross-sectional view of a lift member 420d according to an embodiment.

The lift member 420d may include a dielectric 422, an electrode 421, a pedestal 429, a heater 425, a lower adhesive layer 424, an upper adhesive layer 423, a protective ring 426, and a cooling line 427.

The dielectric 422 may be configured to contact and support a substrate. For example, the substrate may be seated on an upper surface 420s of the dielectric 422. The dielectric 422 uses electrostatic forces to fix the substrate. According to an embodiment, the dielectric 422 may have a circular horizontal cross-sectional shape. However, the dielectric 422 is not necessarily limited to the above shape, and according to another embodiment, the dielectric 422 may have a horizontal cross-sectional shape in a bow shape or a ring shape. Thus, the cross-sectional features shown in FIG. 11 may apply to the embodiments described in any of FIGS. 8-10 above.

According to an embodiment, the electrode 421 may be buried in the dielectric 422. A power source 428 generating the electrostatic force may be connected to the electrode 421. Specifically, the electrode 421 may be connected to the power source 428 generating the electrostatic force for fixing the substrate loaded on an upper surface of the stage table (see 360 in FIG. 7).

The pedestal 429 is disposed on the lower portion of the dielectric 422. In the embodiment, the pedestal 429 may have a circular horizontal cross-sectional shape. However, the pedestal 429 is not necessarily limited to the above shape, and according to another embodiment, the pedestal 429 may have a horizontal cross-sectional shape in a bow shape or a ring shape. In addition, the pedestal 429 and the dielectric 422 may have substantially the same outer diameter.

According to an embodiment, the heater 425 is disposed between the pedestal 429 and the dielectric 422. The heater 425 may heat the substrate seated on the dielectric 422. The heater 425 may have a shorter outer diameter than those of the dielectric 422 and the pedestal 429. Thus, part of a lower surface edge of dielectric 422 and an upper surface edge of pedestal 429 are exposed with respect to the heater 425.

The lower adhesive layer 424 is disposed between the pedestal 429 and the heater 425 to adhere the lower surface of the heater 425 to the upper surface of the pedestal 429. The upper adhesive layer 423 is disposed between the heater 425 and the dielectric 422 to adhere the upper surface of the heater 425 to the lower surface of the dielectric 422. In the embodiment, the lower adhesive layer 424 and the upper adhesive layer 423 may have substantially the same outer diameter. Also, each of the lower adhesive layer 424 and the upper adhesive layer 423 may have substantially the same outer diameter as the outer diameter of the heater 425. Thus, the lower surface edge of the dielectric 422 is exposed from the upper adhesive layer 423. Also, the upper surface edge of the pedestal 429 is exposed from the lower adhesive layer 424. The lower adhesive layer 424 and upper adhesive layer 423 may be formed of a known adhesive material.

The protection ring 426 surrounds the lower adhesive layer 424 and the upper adhesive layer 423. Accordingly, the lower adhesive layer 424 and the upper adhesive layer 423 are not exposed to plasma by the protection ring 426. In addition, the cooling line 427 passing through the lower adhesive layer 424 and the upper adhesive layer 423 may also be protected by the protective ring 426. Therefore, leakage of a cooling fluid flowing through the cooling line 427 may also be prevented.

According to an embodiment, the protection ring 426 may include a material that is not worn by plasma. For example, the protection ring 426 may include ceramic or metal. Specifically, the protection ring 426 may include aluminum.

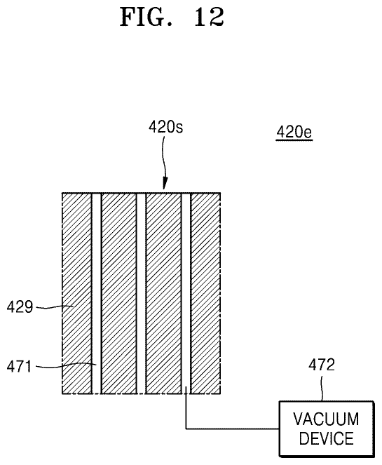

FIG. 12 is a schematic cross-sectional view of a lift member 420e according to another embodiment. Hereinafter, the lift member 420e will be described with reference to FIG. 13D.

The lift member 420e may include the pedestal 429 and a vacuum hole 471. The lift member 420e may have horizontal cross sectional shape such as depicted in any of FIGS. 8-10.

According to an embodiment, the vacuum hole 471 may be configured to vacuum adsorb a semiconductor substrate seated on an upper surface of the stage table (see 420f in FIG. 13D) to the stage table (see 360 in FIG. 13D).

Referring to FIG. 13D, the semiconductor substrate W may be seated on the stage table 360 through the lift pin 410 and the lift member 420. At this time, the vacuum hole 471 of the lift member 420 may vacuum adsorb the semiconductor substrate W toward the stage table 360 so that the bent semiconductor substrate W is disposed to be horizontally close to the upper surface of the stage table 360.

According to an embodiment, the vacuum hole 471 may be connected to a vacuum device 472. When the semiconductor substrate W is seated on the stage table 360, the vacuum device 472 may suck air to make the vacuum hole 471 be in a vacuum state. The vacuum state referred to herein may refer to a state in which the pressure inside the vacuum hole 471 is equal to or less than 1 Torr. That is, the vacuum device 472 may suck air until the pressure inside the vacuum hole 471 is equal to or less than 1 Torr. The vacuum device 472 may discharge air to the vacuum hole 471 when the semiconductor substrate W is unloaded from the stage table 360. As the vacuum device 472 discharges air to the vacuum hole 471, the air pressure inside the vacuum hole 471 may reach the air pressure inside a chamber, and the semiconductor substrate W may be lifted away from the stage table 360 and the lift member 420.

FIGS. 13A to 13F are cross-sectional views schematically illustrating an operation process of a substrate supporting apparatus according to an embodiment.

An operating method of the substrate supporting apparatus 100 below is only an example, and is not limited to the following operating method.

Referring to FIG. 13A, the semiconductor substrate W may descend toward the stage table 360 through a transfer arm (not shown). At this time, the semiconductor substrate W may be convex upward. The plurality of lift pins 410 may respectively move vertically through the openings 408 of the stage table 360. The controller 600 may control the actuator 430 to first lift the lift pins 410 and support the semiconductor substrate W descending toward the stage table 360. After the lift pins 410 engage with and support the semiconductor substrate W, the transfer arm may release the substrate W.

Referring to FIG. 13B, the lift pins 410 may descend while supporting the semiconductor substrate W. At this time, the controller 600 may control the actuator 430 to lift and support the lift member 420 (or lift members) toward the descending substrate W in a state supported by the lift pins 410. The lift member(s) may continue to move upward until they contact the substrate W.

Referring to FIGS. 13C and 13D, after the lift pins 410 and lift member(s) 420 all engage with the substrate W, the controller 600 may control the actuator 430 to cause the lift member(s) 420 to descend and by increasing the descending speed of the lift pin 410 greater than the descending speed of the lift member(s) 420. At this time, the semiconductor substrate W may be convex downward. As a result, a part of the semiconductor substrate W closer to the center region than to the edge region contacts the stage table 360 first. In this manner, the controller 600 may allow the center region of the semiconductor substrate W to first contact the stage table 360, thereby preventing a phenomenon in which the edge region of the semiconductor substrate W slides on the edge region of the stage table 360. Therefore, as shown in FIGS. 3 and 4, a phenomenon in which a protruding part of the edge region of the stage table 360 is damaged may be prevented.

After the center region of the semiconductor substrate W first contacts the stage table 360, the edge region of the semiconductor substrate W may be completely seated on the stage table 360. At this time, an electrode or a vacuum hole of the lift member(s) 420 may allow the semiconductor substrate W to be completely adsorbed to the stage table 360. The actuator controller 440 may allow the lift pin 410 to descend until the upper surface of the lift pin 410 is at least equal to height of the upper surface of the stage table 360.

Referring to FIGS. 13E and 13F, when the semiconductor substrate W is unloaded from the stage table 360, the lift member(s) 420 may lift before the lift pins 410. Specifically, the controller 600 may control the actuator 430 so that the lift member(s) 420 lift before the lift pin 410. As described above, when the lift member(s) 420 lift before the lift pins 410, the edge region of the semiconductor substrate W is detached from the stage table 360 before the center region of the semiconductor substrate W. When the edge region of the semiconductor substrate W is first detached, the probability of the semiconductor substrate W being damaged during the unloading process may be less than when the center region of the semiconductor substrate W is first detached.

The lift member(s) 420 lift so that the edge region of the semiconductor substrate W is detached from the stage table 360, and then, the lift pins 410 may be lifted. Specifically, the controller 600 may control the actuator 430 to support the semiconductor substrate W seated on the stage table 360 by first lifting the lift member(s) 420 and then, to support the semiconductor substrate W by lifting the lift pin 410. The semiconductor substrate W may then be removed from the chamber using the transfer arm.

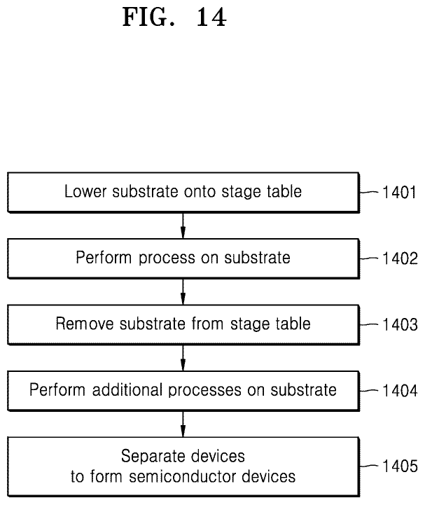

FIG. 14 is a flow chart showing a method of manufacturing a semiconductor device, according to an embodiment. As shown in FIG. 14, in step 1401, a substrate is lowered onto a stage table. The substrate can be a semiconductor substrate used to form a semiconductor device such as a semiconductor chip (e.g., a memory chip or logic chip including an integrated circuit formed thereon). The substrate may be lowered onto the stage table according to the method and using the apparatus described above in connection with FIGS. 1-13F. In step 1402, a process is performed on the substrate. For example, the process may be a deposition process, an etching process, or another process used to form a semiconductor device. In step 1403, the processed substrate is removed from the stage table, for example, according to the method and using the apparatus described above in connection with FIGS. 1-13F. In step 1404, additional processes may be performed on the substrate (e.g., additional etching, deposition, etc.). Each process may include a lowering and removal process such as in steps 1401 and 1403. In step 1405, devices may be separated from each other, e.g., by singulation, to form individual semiconductor devices such as semiconductor chips.

While the inventive concept has been particularly shown and described with reference to embodiments thereof, it will be understood that various changes in form and details may be made therein without departing from the spirit and scope of the following claims.

What is claimed is:

1. A substrate supporting apparatus comprising:
a stage table configured to support a substrate and including a plurality of openings;
a plurality of lift pins disposed to be vertically movable through the plurality of openings and configured to support the substrate;
a lift support positioned outside the stage table from a plan view and vertically movable to support the substrate;
an actuator configured to vertically actuate the plurality of lift pins and the lift support so as to load the substrate onto the stage table; and
a controller configured to control the actuator.

2. The substrate supporting apparatus of claim 1, wherein the lift support includes a dielectric positioned to contact and support the substrate and an electrode connected to a power source configured to generate electrostatic force for fixing the substrate loaded onto an upper surface of the stage table.

3. The substrate supporting apparatus of claim 2, wherein the electrode is buried in the dielectric.

4. The substrate supporting apparatus of claim 1, wherein the stage table includes a plurality of protrusions formed on an upper surface of the stage table to support the substrate.

5. The substrate supporting apparatus of claim 4, wherein the plurality of protrusions are disposed at a certain pitch with respect to each other on the upper surface of the stage table.

6. The substrate supporting apparatus of claim 1, wherein the actuator is configured to lower the plurality of lift pins until an upper surface of each of the plurality of lift pins is at least equal to a height of an upper surface of the stage table.

7. The substrate supporting apparatus of claim 1, wherein:
the lift support includes a plurality of lift members, and
the plurality of lift members are disposed spaced apart from each other along a circumference of the stage table.

8. The substrate supporting apparatus of claim 1, wherein the actuator is configured to independently actuate a vertical movement of the plurality of lift pins and the lift support.

9. The substrate supporting apparatus of claim 1, wherein a shape of an upper surface of the lift support from a horizontal cross section is a circular shape.

10. The substrate supporting apparatus of claim 1, wherein an area of an upper surface of the lift support is larger than an area of an upper surface of each of the plurality of lift pins.

11. A substrate supporting apparatus comprising:
a stage table configured to support a substrate and including a plurality of openings;
a plurality of lift pins disposed to be vertically movable through the plurality of openings and configured to support the substrate;
a lift support positioned outside the stage table from a plan view and vertically movable to support the substrate;
an actuator configured to vertically actuate the plurality of lift pins and the lift support so as to load the substrate onto the stage table;
a controller configured to control the actuator; and
an overlay measurement apparatus positioned on the stage table and configured to measure an overlay between patterns formed on the substrate.

12. The substrate supporting apparatus of claim 11, wherein the lift support includes a vacuum hole vacuum adsorbing the substrate loaded onto an upper surface of the stage table to the stage table.

13. The substrate supporting apparatus of claim 11, wherein a shape of an upper surface of the lift support from a horizontal cross section is a bow shape.

14. The substrate supporting apparatus of claim 11, wherein the controller is configured to control the actuator to support the substrate descending toward the stage table by first lifting the plurality of lift pins, and then to support the substrate by lifting the lift support.

15. The substrate supporting apparatus of claim 11, wherein the controller is configured to control the actuator to support the substrate being unloaded from the stage table by first lifting the lift support, and by lifting the plurality of lift pins.

16. The substrate supporting apparatus of claim 11, wherein an area of an upper surface of the lift support is larger than an area of an upper surface of each of the plurality of lift pins.

17. The substrate supporting apparatus of claim 11, wherein
the lift support includes a plurality of lift members, and
the plurality of lift members are disposed spaced apart from each other along a circumference of the stage table.

18. The substrate supporting apparatus of claim 11, wherein the overlay measurement apparatus is configured to measure the overlay between the patterns between a first layer and a second layer included in a multilayer structure formed on the substrate after the substrate is loaded onto the stage table.

19. A substrate supporting apparatus comprising:
a stage table configured to support a substrate and including a plurality of openings;
a plurality of lift pins disposed to be vertically movable through the plurality of openings and configured to support the substrate;
a plurality of lift members positioned outside the stage table from a plan view, disposed spaced apart from each other along a circumference of the stage table, and vertically movable to support the substrate;
an actuator configured to control a vertical movement of the plurality of lift pins and the plurality of lift members so as to load the substrate onto the stage table; and
a controller configured to control the actuator,
wherein the lift member includes a dielectric positioned to contact and support the substrate and an electrode buried in the dielectric and connected to a power source configured to generate electrostatic force for fixing the substrate loaded onto an upper surface of the stage table,
wherein the stage table comprises a plurality of protrusions disposed at a certain pitch on an upper surface of the stage table to support the substrate,
wherein the actuator is configured to lower the plurality of lift pins until an upper surface of each of the plurality of lift pins is at least equal to a height of the upper surface of the stage table, and independently actuate the vertical movement of the plurality of lift pins and the plurality of lift members, and
wherein a horizontal cross sectional shape of an upper surface of each lift member is a circular or bow shape, and an area of the upper surface of each lift member is larger than an area of the upper surface of each of the plurality of lift pins.

20. The substrate supporting apparatus of claim 19, wherein:
the controller is configured to:
control the actuator to support the substrate descending toward the stage table by first lifting the plurality of lift pins, and then to support the substrate by lifting the plurality of lift members,
control the actuator to subsequently support the substrate descending toward the stage table by first lowering the lift pins, and then by lowering the plurality of lift members, and
to control the actuator to stop the lowering of the plurality of lift pins when a height of an upper surface of each lift pin is equal to a height of the upper surface of the stage table.
